(19) United States
(12) Patent Application Publication
(10) Pub. No.: US 2008/0308315 A1
(43) Pub. Date: Dec. 18, 2008

(54) Multilayer printed circuit board and method of fabricating the same

(75) Inventors: Jee Soo Mok, Gyunggi-do (KR); Jun Heyoung Park, Gyunggi-do (KR); Ki Hwan Kim, Gyunggi-do (KR); Sung Yong Kim, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/004,424

(22) Filed: Dec. 21, 2007

(30) Foreign Application Priority Data
Jun. 13, 2007 (KR) 10-2007-0057711

(51) Int. Cl. H05K 1/11; H05K 3/02

(52) U.S. Cl. 174/264; 216/20

(57) ABSTRACT

This invention relates to a multilayer printed circuit board and a method of fabricating the same, which can increase the reliability of the multilayer printed circuit board and can decrease the process time to thus improve productivity.

### CROSS REFERENCE TO RELATED APPLICATION

This application claims the benefit of Korean Patent Application No. 10-2007-0057711, filed on Jun. 13, 2007, entitled “Multi layer printed circuit board and fabricating method of the same”, which is hereby incorporated by reference in its entirety into this application.

### BACKGROUND OF THE INVENTION

1. Field of the Invention

The present invention relates, in general, to a multilayer printed circuit board (multilayer PCB) and a method of fabricating the same, and more particularly, to a multilayer PCB and a method of fabricating the same, which can increase the reliability of the multilayer PCB and can decrease the process time, to thus improve productivity.

2. Description of the Related Art

In order to realize high-density PCBs with the development of electronic components, there is a demand for techniques for improving the performance of HDI (High Density Interconnection) substrates to which the interlayer electrical connection of circuit patterns and micro-circuit wiring are applied. Specifically, improvement in the performance of the HDI substrate requires techniques for ensuring the interlayer electrical connection of circuit patterns and the freedom of design thereof.

Conventionally, a multilayer PCB is fabricated by forming inner circuits on the surfaces of a core substrate, for example, a copper clad laminate (CCL), through an additive method or a subtractive method, sequentially building up insulating layers and circuit layers, and forming outer circuits through the same method as for the inner circuits.

However, such a conventional process of fabricating the multilayer PCB does not satisfy requests for low costs due to a fall in the price of the application products thereof, including mobile phones, and for a reduction in lead-time to increase mass production, and thus a novel fabrication process that is able to solve these problems is required.

In order to simplify the complicated process of the prior art and to rapidly and inexpensively fabricate a multilayer PCB using a collective lamination procedure, so-called B2it (Buried Bump Interconnection Technology) has been commercialized, which allows simple and convenient lamination by printing a conductive paste on a copper foil to thus form bumps, and laminating an insulation element thereon to prefabricate a paste bump board.

FIGS. 1A to 1H are sectional views sequentially illustrating the process of fabricating a multilayer PCB according to a conventional technique, and FIG. 2 is a view illustrating the formation of paste bumps in the process of fabricating the multilayer PCB, as illustrated in FIGS. 1A to 1H, according to a conventional technique.

With reference to FIGS. 1A to 1H and 2, in the process of fabricating the multilayer PCB according to a conventional technique, as illustrated in FIG. 1A, a first substrate 100 is prepared by forming a first inner circuit pattern 106 on both surfaces of a first insulating layer 102, laminating a second insulating layer 104 having a second inner circuit pattern 108 on both surfaces of the first insulating layer 102, and then forming a first via hole 110 through the first insulating layer 102 and the second insulating layer 104.

Next, as illustrated in FIG. 1B, paste bumps 112 are formed on a copper foil 114a.

The paste bump 112 is formed by repeating printing and drying of a conductive paste 4˜5 times using a mask, as illustrated in FIG. 2.

After the formation of the paste bumps 112, as illustrated in FIG. 1C, a third insulating layer 116 is laminated on the paste bumps 112 such that the paste bumps 112 pass through the third insulating layer 116, which has a thickness of 40˜60 μm, thus preparing a second substrate 130.

Next, as illustrated in FIG. 1D, the second substrate 130 having the paste bumps 112 is laminated on both surfaces of the first substrate 100 so that the paste bumps 112 are attached to the second inner circuit pattern 108.

After the lamination of the second substrate 130 on the first substrate 100, as illustrated in FIG. 1E, a third inner circuit pattern 118 is formed on the third insulating layer 116 through an imaging procedure.

After the formation of the third inner circuit pattern 118, as illustrated in FIG. 1F, a fourth insulating layer 120 and a copper foil 114b are sequentially laminated on the third inner circuit pattern 118.

Next, as illustrated in FIG. 1G, second via holes 122, which are a type of blind via hole, are formed to expose the third inner circuit pattern 118 having the paste bumps 112.

After the formation of the second via hole 122, as illustrated in FIG. 1H, an outer circuit pattern 124 is formed on the fourth insulating layer 120 through an imaging procedure.

In the case where a multilayer PCB having a pitch of 0.4 mm is fabricated through the method of fabricating the multilayer PCB according to a conventional technique, the circuit pattern 118 of the land region is typically formed to have a width of about 250 μm, and the width of the paste bump 112 formed on the circuit pattern 118 of the land region is 130˜150 μm at the bottom thereof, which is narrower than the width of the circuit pattern 118.

Accordingly, because the paste bump 112 is formed so as to be narrow at the bottom thereof, that is, because the hole in the mask for printing the conductive paste is small, repetitive printing and drying of the conductive paste must be conducted in order to form the paste bump 112 to a sufficient height to be able to pass through the third insulating layer 116 having a predetermined height, for example, a thickness of 40˜60 μm, and thus the process time required to form the paste bump 112 is lengthened and the process time required to fabricate the multilayer PCB is also lengthened, undesirably decreasing productivity.

### SUMMARY OF THE INVENTION

Accordingly, the present invention provides a multilayer PCB and a method of fabricating the same, which can improve the reliability of the multilayer PCB and can decrease the process time to thus improve productivity.

According to the present invention, a multilayer PCB may include a first substrate, prepared by forming a first inner circuit pattern on each of both surfaces of a first insulating layer, laminating a second insulting layer having a second circuit pattern on each of both surfaces of the first insulating layer, and forming a first via hole through the first insulating layer and the second insulating layer; a second substrate, prepared by forming a third inner circuit pattern on one surface of a third insulating layer to correspond a portion of the second inner circuit pattern, forming an outer circuit pattern on the other surface of the third insulating layer, and forming a second via hole to electrically connect the third inner circuit pattern and the outer circuit pattern; a fourth insulating layer, interposed between the first substrate and the second substrate; and a paste bump, formed to completely enclose the third inner circuit pattern and connected to the second inner circuit pattern through the fourth insulating layer.

In addition, according to the present invention, a method of fabricating a multilayer PCB may include a) preparing a first substrate by forming a first inner circuit pattern on each of both surfaces of a first insulating layer, laminating a second insulting layer having a second circuit pattern on each of both surfaces of the first insulating layer, and forming a first via hole through the first insulating layer and the second insulating layer; b) preparing a second substrate by forming a third inner circuit pattern on one surface of a third insulating layer to correspond a portion of the second inner circuit pattern, and forming a window in which a portion of a laminated copper foil is etched on the other surface of the third insulating layer; c) forming a paste bump on the third inner circuit pattern and the third insulating layer to completely enclose the third inner circuit pattern; d) laminating a fourth insulating layer on the second substrate having the paste bump formed thereon; e) laminating the second substrate having the fourth insulating layer laminated thereon on each of both surfaces of the first substrate so that the paste bump is brought into contact with the second inner circuit pattern; f) forming a second via hole in the window to expose the third inner circuit pattern; and g) forming an outer circuit pattern on the other surface of the third insulating layer.

### BRIEF DESCRIPTION OF THE DRAWINGS

The features and advantages of the present invention will be more clearly understood from the following detailed description, taken in conjunction with the accompanying drawings, in which:

FIGS. 1A to 1H are sectional views sequentially illustrating the process of fabricating a multilayer PCB, according to a conventional technique;

FIG. 2 is a view illustrating the formation of paste bumps in the process of fabricating the multilayer PCB, as illustrated in FIGS. 1A to 1H, according to a conventional technique;

FIG. 3 is a sectional view illustrating a multilayer PCB, according to the present invention;

FIGS. 4A to 4H are sectional views sequentially illustrating the process of fabricating the multilayer PCB, according to the present invention; and

FIG. 5 is a view illustrating the formation of paste bumps in the process of fabricating the multilayer PCB, as illustrated in FIGS. 4A to 4H, according to the present invention.

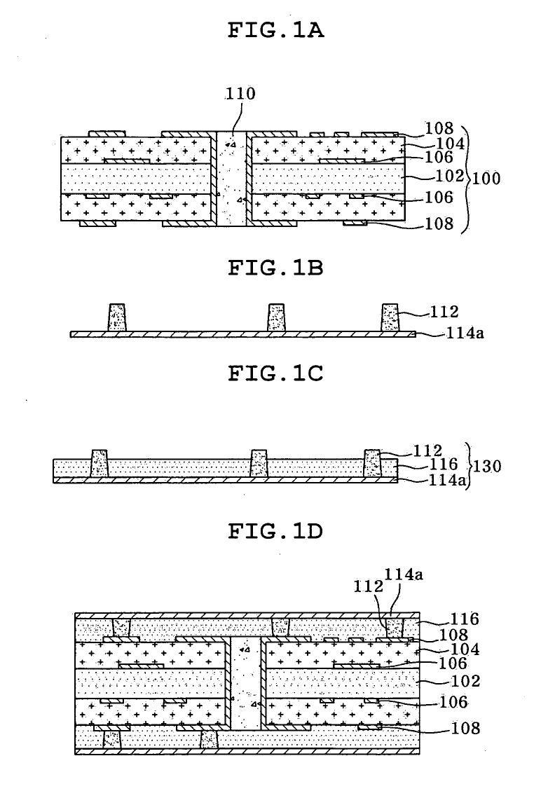

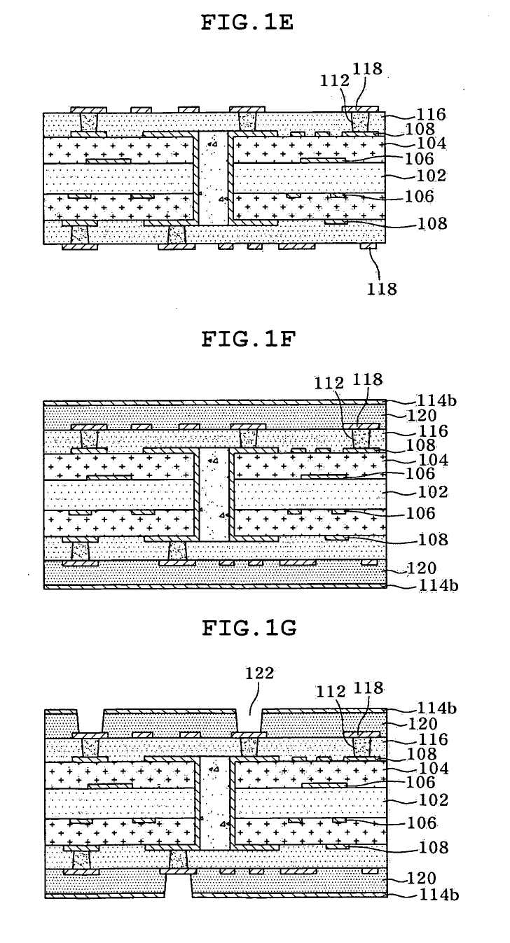

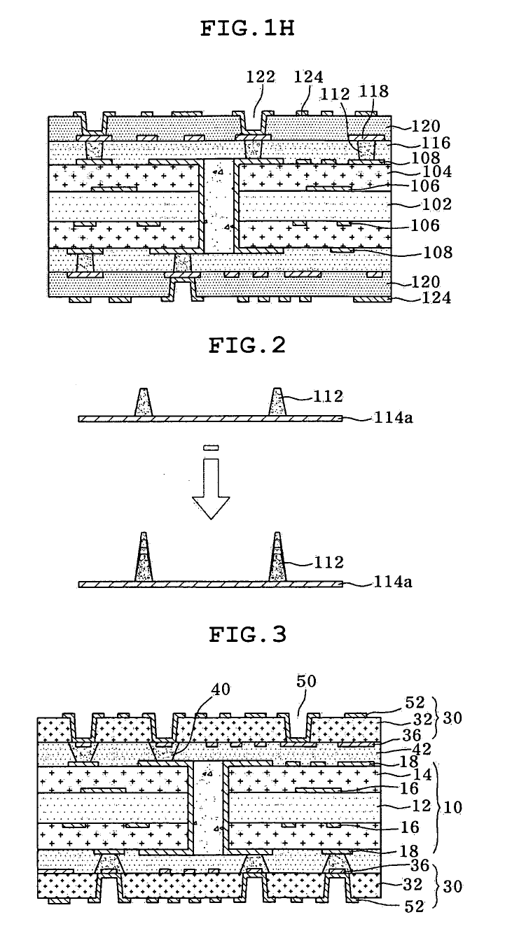

### DESCRIPTION OF THE PREFERRED EMBODIMENTS

Unless otherwise defined, all terms used herein have the same meaning as commonly understood by one having ordinary skill in the art to which the present invention belongs. It will be further understood that terms, such as those defined in commonly used dictionaries, should be interpreted as having meanings consistent with their meanings in the context of the relevant art, and are not to be interpreted in an idealized or overly formal sense unless expressly so defined herein.

Hereinafter, a detailed description will be given of a multilayer PCB and a method of fabricating the same, according to the present invention, with reference to the appended drawings.

FIG. 3 is a sectional view illustrating a multilayer PCB according to the present invention.

As illustrated in FIG. 3, the multilayer PCB according to the present invention includes a first substrate 10, prepared by forming a first inner circuit pattern 16 on both surfaces of a first insulating layer 12, laminating a second insulting layer 14 on both surfaces of the first insulating layer 12, forming a second inner circuit pattern 18 on the second insulating layer 14, and forming a first via hole 20 through the first insulating layer 12 and the second insulating layer 14 to electrically connect the second inner circuit pattern 18; a second substrate 30, prepared by forming a third inner circuit pattern 36 on one surface of a third insulating layer 32 to correspond a portion of the second inner circuit pattern 18, forming an outer circuit pattern 52 on the other surface of the third insulating layer 32, and forming second via holes 50 to electrically connect the third inner circuit pattern 36 and the outer circuit pattern 52; a fourth insulating layer 42, interposed between the first substrate 10 and the second substrate 30; and paste bumps 40, formed to completely enclose the third inner circuit pattern 36 so as to electrically connect the second inner circuit pattern 18 and the third inner circuit pattern 36, and connected to the second inner circuit pattern 18 through the fourth insulating layer 42.

The first substrate 10 is prepared by forming the first inner circuit pattern 16 on both surfaces of the first insulating layer 12, laminating the second insulting layer 14 on both surfaces of the first insulating layer 12, forming the second inner circuit pattern 18 on the second insulating layer 14, and forming the first via hole 20 through the first insulating layer 12 and the second insulating layer 14 to electrically connect the second inner circuit pattern 18.

Although the first substrate 10 is formed into a four-layer structure in which four circuit layers are formed on both surfaces of each of the first and second insulating layers 12, 14, it may be formed to have a two-layer structure, in which the first inner circuit pattern 16 is formed on both surfaces of the first insulating layer 12 and the via hole is formed through the first insulating layer 12.

The first substrate 10 may further include a plurality of insulating layers and circuit pattern layers on the second inner circuit pattern 18, depending on the end use of PCBs.

The first via hole 20 in the first substrate 10 is filled with a conductive paste or an insulating paste.

The second substrate 30 is prepared by forming the third inner circuit pattern 36 and the outer circuit pattern 52 on both surfaces of the third insulating layer 32, and forming the second via holes 50, which are a type of blind via hole, to electrically connect the third inner circuit pattern 36 and the outer circuit pattern 52.

The fourth insulating layer 42 is interposed between the first substrate 10 and the second substrate 30 to electrically disconnect the second inner circuit pattern 18 of the first substrate 10 and the third inner circuit pattern 36 of the second substrate 30.

The paste bump 40 is formed to completely enclose the third inner circuit pattern 36, and is connected to the second inner circuit pattern 18 through the fourth insulating layer 42.

To this end, the paste bump 40 is formed so as to be wider at the bottom thereof than the third inner circuit pattern 36.

Accordingly, the paste bump 40 is formed on the upper and side surfaces of the third inner circuit pattern 36 and on the third insulating layer 32, to completely enclose the third inner circuit pattern 36.

In the multilayer PCB according to the present invention, because the paste bump 40 is formed to completely enclose the third inner circuit pattern 36 of the land region, the contact area between the paste bump 40 and the third inner circuit pattern 36 is enlarged to thus increase the reliability of adhesion between the paste bump 40 and the third inner circuit pattern 36, thereby improving the reliability of the multilayer PCB.

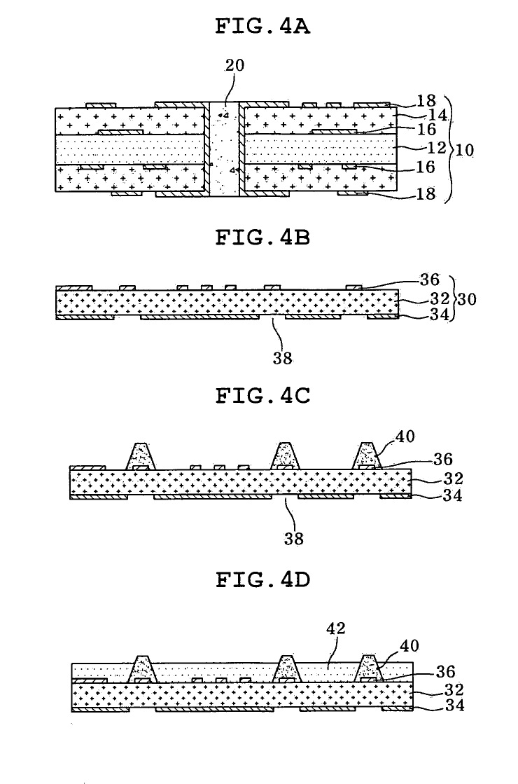

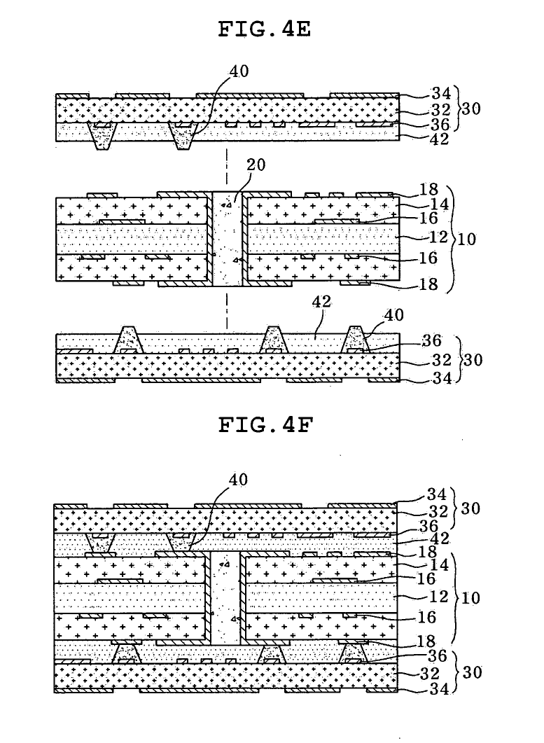

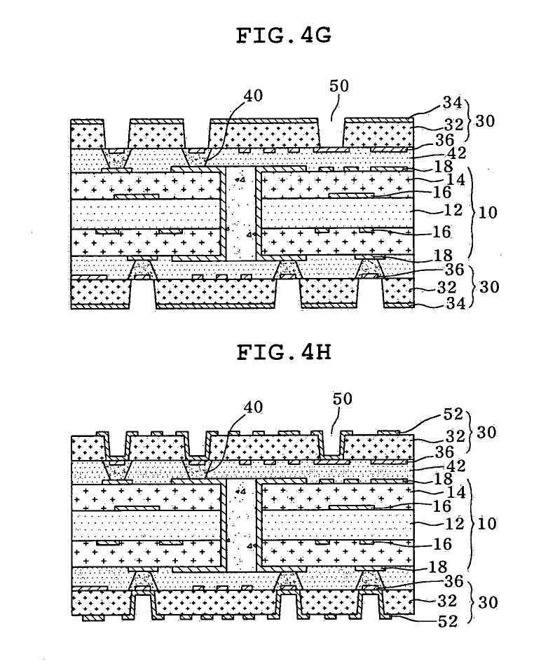

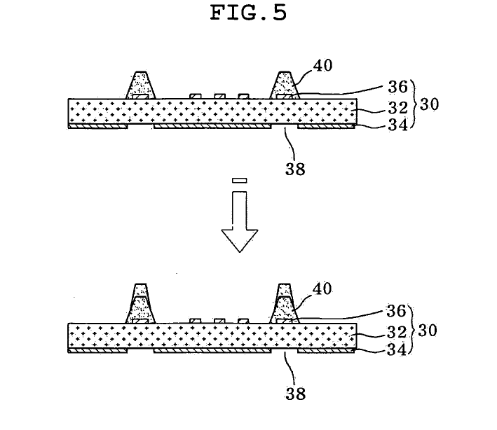

FIGS. 4A to 4H are sectional views sequentially illustrating the process of fabricating the multilayer PCB, as illustrated in FIG. 3, according to the present invention, and FIG. 5 is a view illustrating the formation of paste bumps in the process of fabricating the multilayer PCB, as illustrated in FIGS. 4A to 4H, according to the present invention.

With reference to FIGS. 4A to 4H and 5, in the method of fabricating the multilayer PCB according to the present invention, a CCL, in which a copper foil is laminated on each of both surfaces of a first insulating layer 12, is prepared, after which a photosensitive material (not shown), such as a dry film or a photoresist, is applied on the copper foil thereof.

After the application of the photosensitive material, such as a dry film or a photoresist, the portion of the photosensitive material, such as a dry film or a photoresist, other than the portion of the photosensitive material, such as a dry film or a photoresist, corresponding to a circuit pattern, is removed through exposure and development.

Next, the copper foil, which is exposed by removing the portion of the photosensitive material, such as a dry film or a photoresist, is etched using an etchant, thus forming the first inner circuit pattern 16.

After the formation of the first inner circuit pattern 16, the photosensitive material, such as a dry film or a photoresist, which remains on the first inner circuit pattern 16, is removed.

Next, the second insulating layer 14 and the copper foil are sequentially placed on each of both surfaces of the first insulating layer 12, that is, on the first inner circuit pattern 16, and are then heated and compressed using a press, thus laminating the second insulating layer 14 and the copper foil on both surfaces of the first insulating layer 12.

After the lamination of the second insulating layer 14 and the copper foil, the first via hole 20 is formed through the first insulating layer 12 and the second insulating layer 14 using a CNC (Computer Numerical Control) drill or a laser drill.

After the formation of the first via hole 20, an electroless copper plating layer and a copper electroplating layer are sequentially formed on the inner wall of the first via hole 20 and on the copper foil through electroless copper plating and copper electroplating.

Next, the first via hole 20 is filled with a conductive paste or an insulating paste.

After the filling of the first via hole 20 with the conductive paste or insulating paste, a photosensitive material such as a dry film or a photoresist is applied on the copper electroplating layer, and then the portion of the photosensitive material, such as a dry film or a photoresist, corresponding to a circuit pattern is removed through exposure and development.

Next, the copper foil, which is exposed by removing the portion of the photosensitive material, such as a dry film or a photoresist, is etched using an etchant, thus forming the second inner circuit pattern 18.

Thereby, as illustrated in FIG. 4A, the first substrate 10, having four circuit layers, is prepared.

Although the first substrate 10 has four circuit layers, the first substrate 10, which is a core substrate, may be formed to have two circuit layers, or alternatively may be formed to have four circuit layers or more, depending on the end use of PCBs.

When the first substrate 10 is prepared, the second substrate 30 is prepared, in parallel to the formation of the first substrate 10, that is, at the same time of the formation of the first substrate 10, by forming the third inner circuit pattern 36 on one surface of the third insulating layer 32 and forming a window 38 on the other surface of the third insulating layer 32, as illustrated in FIG. 4B.

The second substrate 30 is prepared as follows.

A CCL, in which a copper foil is laminated on each of both surfaces of a third insulating layer 32, is prepared, after which a photosensitive material, such as a dry film or a photoresist, is applied on the copper foil thereof.

After the application of the photosensitive material, such as a dry film or a photoresist, on the copper foil, the portion of the photosensitive material, such as a dry film or a photoresist, other than the portion of the photosensitive material, such as a dry film or a photoresist, corresponding to the third inner circuit pattern 36, is removed from one surface of the third insulating layer 32 through exposure and development, and the portion of the photosensitive material, such as a dry film or a photoresist, corresponding to the window 38 is removed from the other surface of the third insulating layer 32 through exposure and development.

Next, the copper foil, which is exposed by removing the portion of the photosensitive material, such as a dry film or a photoresist, is removed using an etchant, thus forming the third inner circuit pattern 36 on one surface of the third insulating layer 32, and the window 38, in which the portion of the copper foil 34 is removed, is formed on the other surface of the third insulating layer 32, thereby forming the second substrate 30.

The window 38 and the third inner circuit pattern 36 may be formed at the same time, or alternatively, either one of the window 38 and the third inner circuit pattern 36 may be formed first, and then the other one may be formed.

After the formation of the second substrate 30, a mask, the hole in which is concentric with the central vertical axis of the third inner circuit pattern 36 and has a diameter equal to or greater than the width of the third inner circuit pattern 36, is located on the third inner circuit pattern 36.

Next, a conductive paste is applied on the mask, and is then pressed using a squeegee.

Accordingly, the hole in the mask is filled with the conductive paste, and the bottom of the conductive paste is attached onto the third inner circuit pattern 36 and the third insulating layer 32.

Specifically, the conductive paste is provided to completely enclose the third inner circuit pattern 36 of a via land, in which a blind via hole is formed in a subsequent procedure.

After the printing of the conductive paste, the mask is removed, and the conductive paste is dried through a drying procedure, so that the paste bump 40 is formed on the third inner circuit pattern 36 and the third insulating layer 32 to completely enclose the third inner circuit pattern 36, which is to be used as a land, as seen in FIG. 4C.

Accordingly, the area of the paste bump 40 that is in contact with the third inner circuit pattern 36 is greater than that of a paste bump formed through the method of fabricating a multilayer PCB according to a conventional technique, thus increasing the reliability of adhesion between the paste bump 40 and the third inner circuit pattern 36.

After the formation of the paste bumps 40 on the second substrate 30 to completely enclose the third inner circuit pattern 36, as seen in FIG. 4D, the fourth insulating layer 42 is laminated on the paste bumps 40, so that the paste bumps 40 pass through the fourth insulating layer 42, having a thickness of 40˜60 μm.

Next, as seen in FIG. 4E, the second substrate 30, having the paste bumps 40 passing through the fourth insulating layer 42, is disposed on both surfaces of the first substrate 10, and is then heated and compressed using a press, thus collectively laminating the second substrate 30 on both surfaces of the first substrate 10, as seen in FIG. 4F.

As such, the paste bump 40 is brought into contact with the second inner circuit pattern 18 to thus electrically connect the second inner circuit pattern 18 and the third inner circuit pattern 36.

Next, as seen in FIG. 4G, the second via hole 50, as a type of blind via hole, is formed in the window 38 of the second substrate 30 to expose the third inner circuit pattern 36, using a CNC drill or a laser drill.

After the formation of the second via hole 50, an electroless copper plating layer and a copper electroplating layer are formed on the inner wall of the second via hole 50 and on the copper foil through electroless copper plating and copper electroplating.

After the formation of the copper electroplating layer, a photosensitive material, such as a dry film or a photoresist, is applied on the copper electroplating layer, and then the portion of the photosensitive material, such as a dry film or a photoresist, other than the portion of the photosensitive material, such as a dry film or a photoresist, corresponding to an outer circuit pattern, is removed through exposure and development.

Next, the copper electroplating layer, exposed by removing the portion of the photosensitive material, such as a dry film or a photoresist, the electroless copper plating layer, and the copper foil 34, are removed using an etchant, thus forming the outer circuit pattern 52, as seen in FIG. 4H.

After the formation of the outer circuit pattern 52, the photosensitive material, such as a dry film or a photoresist, which remains on the outer circuit pattern 52, is removed.

In the case where a multilayer PCB having pitches of 0.4 mm is fabricated through the method of fabricating the multilayer PCB according to the present invention, the circuit pattern 36 of the land region, specifically, the third inner circuit pattern 36, which is completely enclosed with the paste bump 40 and has the second via hole 50, is formed to have a width of 80˜150 μm, and the paste bump 40 is formed to have a width of 200˜250 μm at the bottom thereof.

Compared to the method of fabricating a multilayer PCB according to a conventional technique, in the method of fabricating the multilayer PCB according to the present invention, the circuit pattern 36 of the land region may be formed to have a smaller width, thereby fabricating a high-density PCB.

In the method of fabricating the multilayer PCB according to the present invention, the paste bump 40 is formed so as to be wider at the bottom thereof. That is, compared to a conventional technique, in the present invention, when the hole in the mask for printing the conductive paste is enlarged, the separating property of the conductive paste may be improved upon printing of the conductive paste. Therefore, as seen in FIG. 5, in order to form the paste bump 40, which is able to pass through the fourth insulating layer 42 having a predetermined height, for example, a thickness of 40˜60 μm, the number of printings of the conductive paste may be reduced.

Accordingly, the method of fabricating the multilayer PCB according to the present invention can decrease the process time required to form the paste bump 40, thus shortening the process time required to fabricate the multilayer PCB, resulting in improved productivity.

As described hereinbefore, the present invention provides a multilayer PCB and a method of fabricating the same. According to the present invention, the width of a circuit pattern of a land region can be decreased, compared to a conventional technique, thus facilitating the fabrication of high-density multilayer PCBs. As well, because the paste bump is formed to completely enclose the circuit pattern of the land region, the contact area between the paste bump and the circuit pattern is enlarged, thus increasing reliability of adhesion between the paste bump and the circuit pattern, leading to highly reliable PCBs.

Further, compared to a conventional technique, in the present invention, because the paste bump can be formed so as to be wider at the bottom thereof, the hole in a mask used for the formation of the paste bump can be enlarged, thus improving the separating property of the conductive paste, thereby reducing the process time required to form the paste bump.

Therefore, the process time required to fabricate the multilayer PCB can be decreased, consequently improving productivity.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A multilayer printed circuit board, comprising:
a first substrate, prepared by forming a first inner circuit pattern on each of both surfaces of a first insulating layer, laminating a second insulting layer having a second circuit pattern on each of both surfaces of the first insulating layer, and forming a first via hole through the first insulating layer and the second insulating layer;
a second substrate, prepared by forming a third inner circuit pattern on one surface of a third insulating layer to correspond a portion of the second inner circuit pattern, forming an outer circuit pattern on the other surface of the third insulating layer, and forming a second via hole to electrically connect the third inner circuit pattern and the outer circuit pattern;
a fourth insulating layer, interposed between the first substrate and the second substrate; and
a paste bump, formed to completely enclose the third inner circuit pattern and connected to the second inner circuit pattern through the fourth insulating layer.

2. The multilayer printed circuit board as set forth in claim 1, wherein the paste bump is formed so as to be wider at a bottom thereof than the third inner circuit pattern.

3. The multilayer printed circuit board as set forth in claim 2, wherein the paste bump is formed on upper and side surfaces of the third inner circuit pattern and on the third insulating layer, to completely enclose the third inner circuit pattern.

4. A method of fabricating a multilayer printed circuit board, comprising:
a) preparing a first substrate by forming a first inner circuit pattern on each of both surfaces of a first insulating layer, laminating a second insulting layer having a second circuit pattern on each of both surfaces of the first insulating layer, and forming a first via hole through the first insulating layer and the second insulating layer;
b) preparing a second substrate by forming a third inner circuit pattern on one surface of a third insulating layer to correspond a portion of the second inner circuit pattern, and forming a window, in which a portion of a laminated copper foil is etched, on the other surface of the third insulating layer;
c) forming a paste bump on the third inner circuit pattern and the third insulating layer to completely enclose the third inner circuit pattern;
d) laminating a fourth insulating layer on the second substrate having the paste bump formed thereon;
e) laminating the second substrate having the fourth insulating layer laminated thereon on each of both surfaces of the first substrate so that the paste bump is brought into contact with the second inner circuit pattern;
f) forming a second via hole in the window to expose the third inner circuit pattern; and
g) forming an outer circuit pattern on the other surface of the third insulating layer.

5. The method as set forth in claim 4, wherein the a) comprises:
a-1) forming the first inner circuit pattern on each of both surfaces of the first insulating layer;
a-2) laminating the second insulating layer on each of both surfaces of the first insulating layer;
a-3) forming the first via hole through the first insulating layer and the second insulating layer; and
a-4) forming the second inner circuit pattern on the second insulating layer.

6. The method as set forth in claim 4, wherein the b) comprises:
b-1) preparing a copper clad laminate, in which a copper foil is laminated on each of both surfaces of the third insulating layer;
b-2) etching the copper foil from one surface of the third insulating layer, thus forming the third inner circuit pattern on one surface of the third insulating layer; and
b-3) etching the copper foil from the other surface of the third insulating layer, thus forming the window on the other surface of the third insulating layer.

7. The method as set forth in claim 6, wherein the b-2) and the b-3) are simultaneously performed.

8. The method as set forth in claim 4, wherein the c) comprises:
c-1) locating a mask having a hole on a portion of the third inner circuit pattern at which the paste bump is to be formed;
c-2) printing the conductive paste to completely enclose the third inner circuit pattern with the conductive paste; and
c-3) drying the conductive paste, thus forming the paste bump.

9. The method as set forth in claim 8, wherein the hole in the mask is concentric with a central vertical axis of the third inner circuit pattern and has a diameter equal to or greater than a width of the third inner circuit pattern.
